(19) United States
(12) Patent Application Publication
(10) Pub. No.: US 2015/0140838 A1
(43) Pub. Date: May 21, 2015

(54) Two Step Deposition of High-k Gate Dielectric Materials

(71) Applicant: Intermolecular Inc., San Jose, CA (US)

(72) Inventors: Kevin Kashefi, San Jose, CA (US); Amol Joshi, Sunnyvale, CA (US); Salil Mujumdar, San Jose, CA (US)

(73) Assignee: Intermolecular Inc., San Jose, CA (US)

(21) Appl. No.: 14/083,761

(22) Filed: Nov. 19, 2013

(51) Int. Cl. H01L 29/51; H01L 21/02; H01L 21/28

(52) U.S. Cl. CPC H01L 29/517; H01L 21/28229; H01L 21/02181; H01L 21/0228; H01L 21/02318
USPC 438/785

(57) ABSTRACT

Methods and apparatus for forming a dielectric layer for use as a gate dielectric are provided. A high-k layer is formed with first ALD process using a halogen-based precursor. The metal in the halogen-based precursor may be at least one of hafnium, zirconium, or titanium. The halogen in the halogen-based precursor may be at least one of fluorine, chlorine, or iodine. In some embodiments, the halogen-based metal precursor includes hafnium chloride. The remainder of the high-k layer is formed with second ALD process using a metal organic-based precursor. The metal in the metal organic-based precursor may be at least one of hafnium, zirconium, or titanium. The organic ligands in the metal organic-based precursor may be at least one of β-diketonate precursors, alkoxide precursors, amino precursors. In some embodiments, the metal organic-based precursor includes amino precursors.

### TECHNICAL FIELD

The present disclosure relates generally to methods and apparatus for forming high k dielectric layers.

### BACKGROUND

As integrated circuit feature sizes decrease, other device dimensions also decrease to maintain the proper device operation. For example, as gate conductor widths decrease, the thickness of the gate dielectric needs to decrease to provide proper capacitance to control the transistor.

To meet the requirements of sub-20 nm devices, an equivalent oxide thickness (EOT) of less than 1.5 nm is needed. Using SiO₂ as the gate dielectric, it is difficult to maintain its dielectric property below about 2 nm thickness due to the high leakage due to tunneling.

High-k materials, (e.g., dielectric materials having a dielectric constant k greater than that of SiO₂ (k˜3.9)), can provide high capacitance with higher thickness, and thus have been investigated as a replacement for SiO₂. For example, a high-k value of 20, which can be obtained with various transition metal oxides such as hafnium oxide, can be about five times thicker than a SiO₂ film with similar capacitance value. The thicker gate dielectric layer of the high-k material can reduce tunneling leakage current through the gate, enabling sub-20 nm MOSFET devices.

The fabrication of high-k gate dielectric layers can provide difficulty in realizing the full benefits of the high dielectric constant. For example, processing high-k dielectric layers in the presence of oxygen at elevated temperatures, (e.g., high-k deposition or subsequent anneal processes), can form a SiO₂ interfacial layer between the silicon substrate and the high-k layer. The SiO₂ interfacial layer can increase the effective oxide thickness, reducing the capacitance of the gate dielectric layer. Further, high-k gate dielectrics can contain a greater number of bulk traps and interface traps than thermally growth SiO₂ gate dielectrics. The traps can degrade the device performance, such as sub-threshold slope, threshold voltage, flatband voltage shift, and Frenkel-Poole tunneling leakage.

Thus there is a need to develop improved methods and structures involving high-k gate dielectrics and related semiconductor devices.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Methods and apparatus for forming a high-k dielectric layer for use as a gate dielectric are provided. In some embodiments, a high-k layer is formed using a first ALD process using a halogen-based precursor. The metal in the halogen-based precursor may be at least one of hafnium, zirconium, or titanium. The halogen in the halogen-based precursor may be at least one of fluorine, chlorine, or iodine. In some embodiments, the halogen-based metal precursor includes hafnium chloride.

In some embodiments, the remainder of the high-k layer is formed using a second ALD process using a metal organic-based precursor. The metal in the metal organic-based precursor may be at least one of hafnium, zirconium, or titanium. The organic ligands in the metal organic-based precursor may be at least one of β-diketonate precursors, alkoxide precursors, amino precursors. In some embodiments, the metal organic-based precursor includes amino precursors.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a cross-sectional schematic diagram of a typical semiconductor device.

FIGS. 2A and 2B illustrate cross-sectional schematic diagrams of a fabrication sequence for a typical semiconductor device.

FIG. 3 illustrates a flow chart of a method according to some embodiments.

FIG. 4 illustrates a processing system enabling deposition according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Before various embodiments are described in detail, it is to be understood that unless otherwise indicated, this invention is not limited to specific layer compositions or surface treatments. It is also to be understood that the terminology used herein is for the purpose of describing particular embodiments only and is not intended to limit the scope of the present invention.

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

The term “substrate” as used herein may refer to any workpiece on which formation or treatment of material layers is desired. Substrates may include, without limitation, silicon, germanium, silicon-germanium alloys, gallium arsenide, indium gallium arsenide, indium gallium antimonide, silica, sapphire, zinc oxide, silicon carbide, aluminum nitride, Spinel, coated silicon, silicon on oxide, silicon carbide on oxide, glass, gallium nitride, indium nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter.

The terms “high-k material”, “high-k layer”, and “high-k dielectric”, as used herein, will be considered to be equivalent and will refer to a material and/or layer that has a dielectric constant of greater than 5.

Advances in semiconductor processing have demanded ever-increasing functional density with continued size scaling. This scaling process has led to the adoption high-k gate dielectrics and metal gate electrodes employed in metal gate stacks in semiconductor devices.

High-k gate dielectrics can offer methods to scale the thickness of the gate dielectric while maintaining acceptable gate leakage current. The use of high-k gate dielectrics is often accompanied by a metal gate electrode, since thin gate dielectric layers may cause depletion in polysilicon electrodes, affecting the device operation and performance. Metal gate electrodes further have an advantage of higher electrical conductance, (e.g. as compared to polysilicon gates), and thus can improve signal propagation times.

The manufacture of high-k dielectric devices entails the integration and sequencing of many unit processing steps, with potential new process developments, since in general, high-k gate dielectrics are more sensitive to process conditions than silicon dioxide. For example, interface traps and interface oxide formation can adversely affect the performance of the high-k gate structures.

The microelectronic industry continues to search for new dielectric materials that exhibit high k values (i.e. materials with a high dielectric constant) and low leakage, to enable further miniaturization of electronic devices. These materials may be used as the dielectric layer in electronic components such as gate dielectric layers, capacitors, memory cell structures, and other devices. The k value is a measure of the polarization capability of dielectric materials in response to an external electrical field, which can be used to store charges in capacitors. The ability of a dielectric material to store charge is also conveniently represented by the capacitive equivalent thickness (“CET”) for gate dielectric layers. A low CET implies an increased ability to miniaturize semiconductor devices. The leakage is a measure of the material's capability to retain stored charge for a certain period of time. Both CET and leakage are important parameters for the miniaturization of electronic components such as gate dielectric layers, capacitors, memory cell structures, and other devices. Typical high-k materials include Al₂O₃ (k^{˜}9), HfSiO (k^{˜}5−20), ZrO₂ (k^{˜}25), HfO₂ (k^{˜}25), Ta₂O₅ (k^{˜}26), and rutile-TiO₂ (k^{˜}80).

Scaling of the gate lengths and CET is forcing the replacement of silicon dioxide as a gate dielectric by materials having high-dielectric constants (i.e., high-k materials). The goals include reduction of leakage currents and meeting requirements of reliability. Some additional consideration in selecting suitable replacement materials include silicon related band offsets, permittivity, dielectric breakdown strength, interface stability and quality with silicon, and the effective masses of the carriers.

In some embodiments, the present invention discloses methods, and structures fabricated from the methods, to form a gate dielectric, for example, hafnium oxide, hafnium silicon oxide (HfSiOₓ), zirconium oxide, or other high k dielectrics. In the following description, hafnium oxide is used to as an illustrative example, but other high k dielectrics can be used, for example, derivatives of hafnium oxide such as hafnium silicon oxide (HfSiOₓ) or hafnium aluminum oxide (HfAlOₓ), or high k dielectrics having similar behaviors as compared to hafnium oxide such as zirconium oxide or zirconium oxide derivatives.

Hafnium oxide is a candidate for silicon dioxide replacement as a gate dielectric material. It has a dielectric constant of about 25 at room temperature or about six times greater than that of silicon dioxide. While this dielectric constant is more than an order of magnitude smaller than for very high-k materials such as strontium titanium oxide (STO), which has a dielectric constant of about 300, hafnium oxide has a conduction band offset of about 1.5-2.0 eV with respect to silicon, which is more than one order of magnitude higher than that of STO.

The same properties of hafnium oxide that make it a leading candidate for a gate dielectric application also give hafnium oxide a high potential for other applications, such as insulating dielectrics in capacitive elements of various memory devices or, more specifically, of dynamic random-access memory (DRAM) capacitor stacks. Because of its high dielectric constant, a thick layer of hafnium oxide can be used to achieve the same performance as a much thinner silicon dioxide layer. However, thicker hafnium oxide layers have much lower leakage currents in comparison with thinner silicon oxide layers. In addition to having a high dielectric constant, hafnium oxide is thermodynamically stable with respect to silicon, with which it may be in contact in many semiconductor applications. Many modern complementary metal-oxide-semiconductor (CMOS) and DRAM processes involve high temperatures (e.g., 600° C.) that are applied to substrates for a few seconds.

Hafnium oxide layers or structures may be deposited by a variety of physical vapor deposition (PVD) methods, including laser pulse ablation and sputtering. Other deposition techniques include chemical vapor deposition (CVD) using β-diketonate precursors, alkoxide precursors, amino precursors, or halogen-based (e.g. chloride) precursors. Atomic layer deposition (ALD) techniques may also be used to prepare layers using β-diketonate precursors, alkoxide precursors, amino precursors, or halogen-based (e.g. chloride) precursors. Different deposition techniques yield different layer structures that may have different performance characteristics.

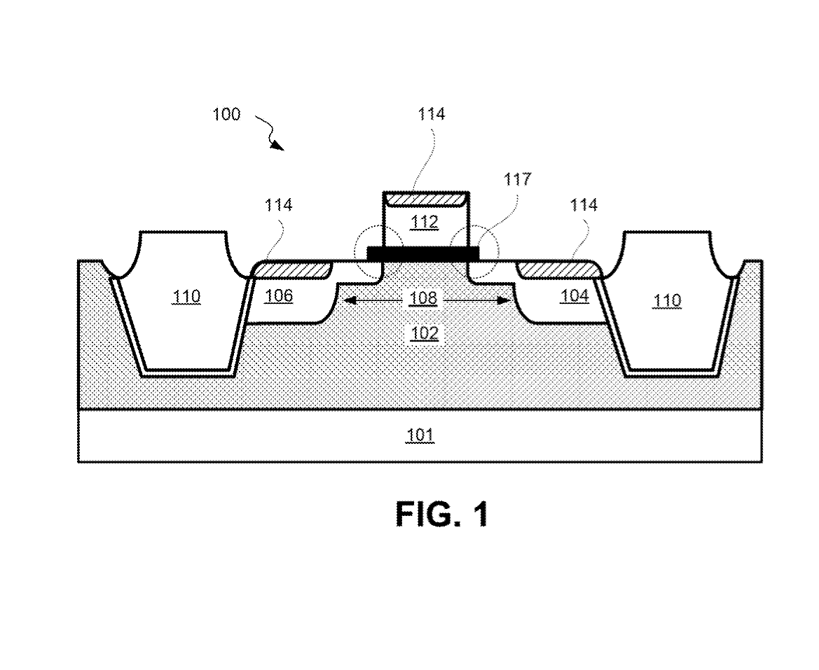

A brief description of semiconductor device examples is presented below to provide better understanding of various plasma surface treatments. Specifically, FIG. 1 illustrates a schematic representation of substrate portions including MOS device, 100, in accordance with some embodiments. The references below are made to positive metal-oxide semiconductor (PMOS) devices but other types of MOS devices can be used in the described processes and will be understood by one having ordinary skill in the art. MOS device, 100, includes a p-doped substrate, 101, and an n-doped well, 102, disposed within substrate, 101. Substrate, 101, is typically a part of an overall wafer that may include other devices. Some of these devices may include silicon nitride, silicon oxide, polysilicon, or titanium nitride structures. P-doped substrate, 101, may include any suitable p-type dopants, such as boron and indium, and may be formed by any suitable technique. N-doped well, 102, may include any suitable n-type dopants, such as phosphorus and arsenic, and may be formed by any suitable technique. For example, n-doped well, 102, may be formed by doping substrate, 101, by ion implantation, for example.

MOS device, 100, also includes a conductive gate electrode, 112, that is separated from n-doped well, 102, by gate dielectric, 117. Gate electrode, 112, may include any suitable conductive material (e.g., titanium nitride, tantalum nitride, hafnium nitride, ruthenium nitride, tungsten nitride, tungsten, molybdenum, tantalum silicon nitride, ruthenium silicon nitride, tungsten silicon nitride, hafnium silicon nitride, titanium silicon nitride, etc). Gate dielectric, 117, is formed from a high-k material (e.g. hafnium oxide). Other dielectric materials include zirconium oxide or aluminum oxide. Typically, a semiconductor material with high mobility such as germanium or a silicon-germanium alloy (not shown) is formed beneath the gate dielectric.

MOS device, 100, also includes p-doped source region, 104, and drain region, 106, (or simply the source and drain) disposed in n-doped well, 102. Source, 104, and drain, 106, are located on each side of gate electrode, 112, forming channel, 108, within n-doped well, 102. Source, 104, and drain, 106, may include a p-type dopant, such as boron. Source, 104, and drain, 106, may be formed by ion implantation. After forming source, 104, and drain, 106, MOS device, 100, may be subjected to an annealing and/or thermal activation process.

In some embodiments, source, 104, drain, 106, and gate electrode, 112, are covered with a layer of self-aligned silicide portions, 114, which may be also referred to as salicide portions or simply salicides. For example, a layer of cobalt may be deposited as a blanket layer and then thermally treated to form these silicide portions, 114. Other suitable materials include nickel and other refractory metals, such as tungsten, titanium, platinum, and palladium. After forming the blanket layer from the suitable metal, the layer is subjected to rapid thermal process (RTP) to react the metal with silicon contained within gate electrode, 112, as well as within source, 104, and drain, 106, to form a metal silicide. The RTP process may be performed at 700° C. to 1000° C.

MOS device, 100, may also include shallow trench isolation (STI) structures, 110, disposed on both sides of source, 104, and drain, 106. STI structures, 110, may include liners formed on the side and bottom walls by, for example, thermal oxidation of silicon of n-doped well, 102. The main body of STI structures is formed by filling a trench within n-doped well, 102, with a dielectric material, such as silicon oxide. Silicon oxide may be filled using high density plasma (HDP) deposition process.

As shown in FIG. 1, gate dielectric, 117, may protrude beyond gate electrode, 112. As such, gate dielectric, 117, may need to be partially etched such that it does not extend past electrode, 112, and does not interfere with subsequent formation of liners and spacers on sidewalls of gate electrode, 112.

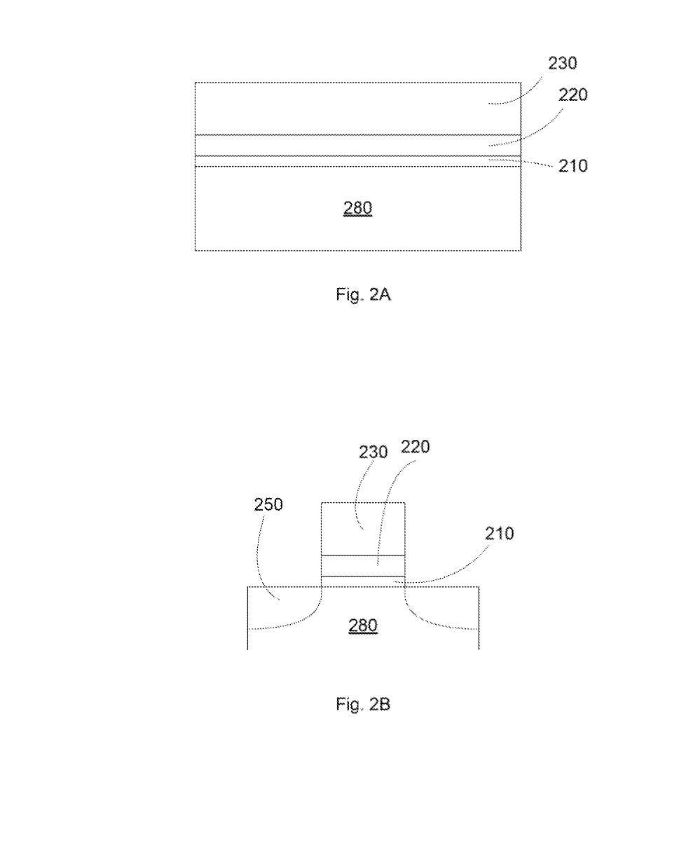

FIGS. 2A-2B illustrate a fabrication sequence for an exemplary gate according to some embodiments. In FIG. 2A, blanket layers of gate dielectric layer, 210, metal gate layer, 220, and gate conductor layer, 230, are deposited on a substrate, 280. The substrate, 280, can be previously processed, for example, to form device well and isolation regions. The structure shown is illustrative, and other configurations can be used, such as (1) a single metal gate layer instead of a metal gate layer, 220, and a gate conductor layer, 230, or (2) a gate dielectric layer stack comprising a high-k dielectric layer on a silicon dioxide pedestal layer instead of a single gate dielectric layer, 210.

The gate dielectric layer, 210, can be formed of a layer of hafnium oxide deposited using a halogen-based hafnium containing precursor, or it may be formed of a bi-layer of organometallic-based hafnium oxide formed above a halogen-based hafnium oxide, fabricated using two step deposition with halogen-based hafnium containing precursor and organometallic-based hafnium containing precursor. The halogen-based hafnium oxide can improve the performance characteristics of semiconductor devices by lowering the leakage current through the gate stack. In some embodiments, the thickness of the gate dielectric is less than 10 nm, for example, less than 3 nm. The thickness of the fluorinated hafnium oxide layer can be less than 2 nm, such as less than 1 nm. The thickness of the hafnium oxide layer can be less than 4 nm, such as less than 2 nm. The gate dielectric layer, 210, can be formed by deposition, such as an ALD process.

Disposed on the gate dielectric layer, 210, is a metal gate layer, 220, together with a gate conductor layer, 230. Alternatively, the gate conductor layer, 230, can be omitted, leaving only a metal gate layer, 220. The metal gate layer, 220, typically includes a first metal, and the gate conductor, 230, can either include a polysilicon or a second metal, different from the first metal. In some embodiments, the metal gate layer, 220, is a metal-containing layer, having a metal component together with other combination of materials.

The metal gate layer, 220, can include a refractory metal or a nitride of a refractory metal, such as titanium nitride. Alternatively, the metal gate layer, 220, can include other conductive materials (e.g., titanium nitride, tantalum nitride, hafnium nitride, ruthenium nitride, tungsten nitride, tungsten, molybdenum, tantalum silicon nitride, ruthenium silicon nitride, tungsten silicon nitride, hafnium silicon nitride, titanium silicon nitride, etc). The thickness of the metal gate layer, 220, can be less than 20 nm with the gate conductor layer, or can be less than 200 nm without a gate conductor layer.

The gate conductor layer, 230, can include silicon, such as doped polysilicon. Alternatively, the gate conductor layer, 230, can include a second metal, different from the first metal in the metal gate layer, 220. In addition, the gate conductor can be omitted. The thickness of the gate conductor can be less than 200 nm.

The metal gate layer, 220, and gate conductor layer, 230, can be formed by any methods, such as atomic layer deposition (ALD), physical vapor deposition (PVD), or chemical vapor deposition (CVD).

FIG. 2B shows a device having the gate conductor layer, 230, the metal gate, 220, and the gate dielectric, 210. Any patterning process can be used, for example, lithography patterning process using photoresist mask and dry or wet etching. The layers can be patterned using a plasma etch process or a wet etch process.

After the completion of the metal gate electrode, the substrate can be further processed to form active devices and circuits. For example, additional steps of implanting dopants to form source and drain structures, 250, forming gate spacers, and shallow junctions. Interconnect metal lines can be included, connecting a plurality of active devices to form an integrated circuit. There can be silicide regions (not shown) on the gate conductor layer, 230, for improving contact resistance. The device shown is an exemplary planar device configuration, and other device configurations are also within the scope of the present invention, such as tri-gate transistor configurations, fin-FET configurations, or different types of transistors or devices.

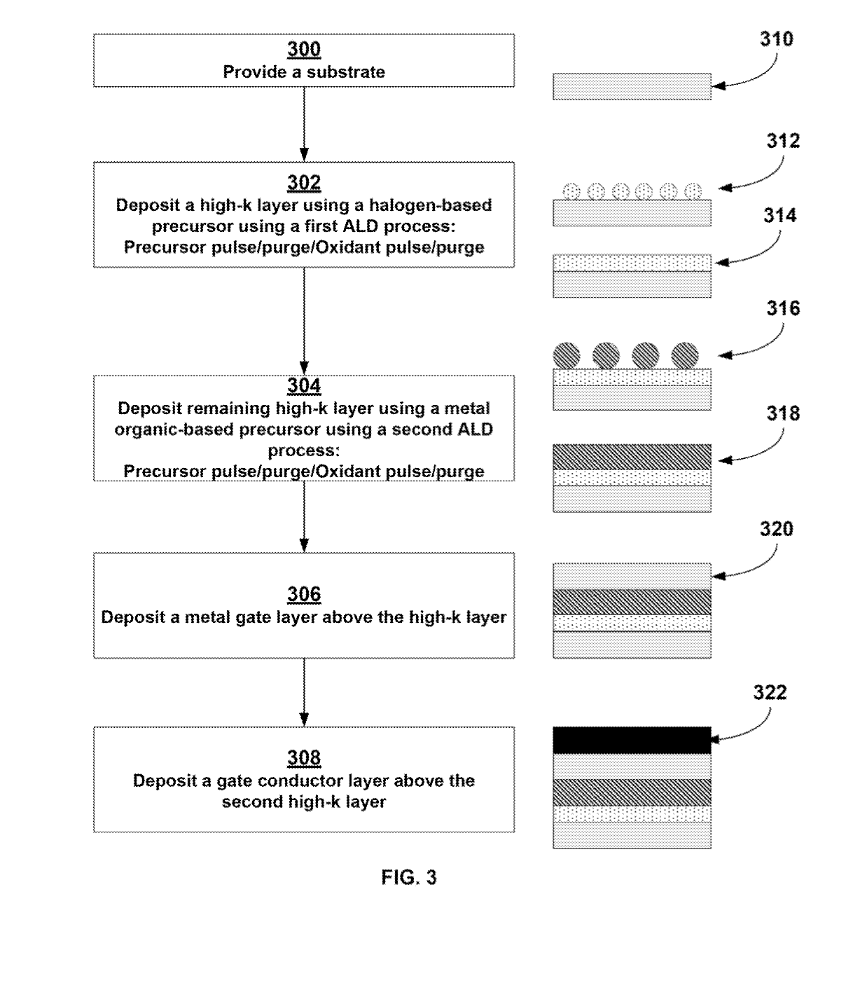

FIG. 3 illustrates a flow chart and a schematic of conventional ALD deposition of gate dielectric layers. This sequence only discusses the steps involved in the formation of the gate stack. In step 300, a substrate, 310, is provided. Typically, the substrate will have been subjected to a number of previous processing steps and may have a number of structures formed thereon.

In step 302, a high-k layer (e.g. a high-k metal oxide) is formed above the substrate using a first ALD process using a halogen-based precursor. In some embodiments, the metal of the high-k layer includes at least one of hafnium, zirconium, or titanium. In some embodiments, the halogen of the halogen-based precursor includes at least one of fluorine, chlorine, or iodine. In some embodiments, the halogen-based precursor includes hafnium chloride. A portion of the halogen-based precursor adsorbs onto the surface at reactive sites, 312. The remainder of the precursor is purged from the reaction zone. An oxidant is then pulsed into the reaction zone to react with the adsorbed precursor and form a high-k metal oxide dielectric layer, 314 that acts as a gate dielectric layer. This sequence may be repeated several times to form a first high-k layer that has a thickness of between about 0.3 nm to 1 nm.

In step 304, the remaining high-k layer (e.g. a high-k metal oxide) is formed above the initial high-k layer using a second ALD process using a metal organic-based precursor. In some embodiments, the metal of the high-k layer includes at least one of hafnium, zirconium, or titanium. In some embodiments, the ligand of the metal organic-based precursor includes at least one of β-diketonate precursors, alkoxide precursors, or amino precursors. In some embodiments, the metal organic-based precursor includes tetrakis(dimethylamino)hafnium (TDMAHf). A portion of the metal organic-based precursor adsorbs onto the surface at reactive sites, 316. The remainder of the precursor is purged from the reaction zone. An oxidant is then pulsed into the reaction zone to react with the adsorbed precursor and form a high-k metal oxide dielectric layer, 318 that acts as a gate dielectric layer. This sequence may be repeated several times to form a second high-k layer that has a thickness of between 0.3 nm and 3 nm.

In step 306, a metal gate layer, 320, is deposited above the second high-k layer. The metal gate layer, 320, can include a refractory metal or a nitride of a refractory metal, such as titanium nitride. Alternatively, the metal gate layer 320 can include other conductive materials (e.g., titanium nitride, tantalum nitride, hafnium nitride, ruthenium nitride, tungsten nitride, tungsten, molybdenum, tantalum silicon nitride, ruthenium silicon nitride, tungsten silicon nitride, hafnium silicon nitride, titanium silicon nitride, etc). The thickness of the metal gate layer, 320, can be less than 20 nm with a gate conductor layer, or can be less than 200 nm without a gate conductor layer.

In step 308, a gate conductor layer, 322, is deposited above the metal gate layer. The gate conductor layer, 322, can include silicon, such as doped polysilicon. Alternatively, the gate conductor layer, 322, can include a second metal, different from the first metal in the metal gate layer, 320. In addition, the gate conductor can be omitted. The thickness of the gate conductor can be less than 200 nm.

The metal gate layer, 320, and gate conductor layer, 322, can be formed by any methods, such as atomic layer deposition (ALD), physical vapor deposition (PVD), or chemical vapor deposition (CVD).

High-k dielectric layers (e.g. hafnium oxide) deposited on germanium substrates and/or layers using metal organic precursors (e.g. TDMAHf) have been shown to exhibit lower leakage current as compared to high-k materials layers using inorganic and/or halogen-based (e.g. HfCl₄) precursors. Similar trends for high-k layers deposited on silicon substrates and/or layers have not been observed. Without being bound by any particular theory, it is believed that this is due to the difference in nucleation of the metal organic precursors versus the inorganic and/or halogen-based precursors on germanium versus silicon.

In some embodiments, the benefits of the lower leakage current observed for high-k layers deposited on germanium substrates and/or layers using metal organic precursors can be extended to high-k layers deposited on silicon substrates and/or layers by forming the high-k layer from two sub-layers.

In some embodiments, a high-k layer is deposited using a first ALD process using a halogen-based precursor. The first ALD process is repeated a number of times to deposit a high-k layer having a thickness of about 0.3 nm. In some embodiments, the metal of the high-k layer includes at least one of hafnium, zirconium, or titanium. In some embodiments, the halogen of the halogen-based precursor includes at least one of fluorine, chlorine, or iodine. In some embodiments, the halogen-based precursor includes hafnium chloride.

In some embodiments, the remainder of the high-k layer is deposited using a second ALD process using a metal organic-based precursor. The second ALD process is repeated a number of times to deposit a second portion of the high-k layer having a thickness of between about 0.3 nm and 1.5 nm. In some embodiments, the metal of the high-k layer includes at least one of hafnium, zirconium, or titanium. In some embodiments, the ligand of the metal organic-based precursor includes at least one of β-diketonate precursors, alkoxide precursors, or amino precursors. In some embodiments, the metal organic-based precursor includes tetrakis(dimethylamino)hafnium (TDMAHf).

The ALD processes for depositing or otherwise forming gate dielectric materials are typically conducted in a deposition chamber, such as an ALD chamber. The deposition chamber may maintain an internal pressure of less than 760 Torr, such as within the range from about 10 mTorr to about 10 Torr, such as from about 100 mTorr to about 1 Torr, for example, about 350 mTorr. The temperature of the device, the substrate, or the substrate carrier/pedestal is usually maintained within the range from about 50° C. to about 1,000° C., such as from about 100° C. to about 500° C., such as from about 200° C. to about 400° C., or such as from about 250° C. to about 300° C.

The metal oxide precursor may be pulsed or otherwise provided into the deposition chamber at a rate within a range from about 0.01 seconds to about 60 seconds, depending on the particular process conditions, precursors or desired composition of the deposited oxide materials.

In some embodiments, the metal oxide precursor is a hafnium inorganic precursor, such as hafnium chloride (HfCl₄), hafnium iodine (Hfl₄), or anhydrous hafnium nitrate (Hf(NO₃)₄). The halogen-based precursor, (e.g., hafnium chloride), can be pulsed, introduced, or otherwise provided into the deposition chamber at a flow rate within the range from about 0.1 sccm to about 1000 sccm, such as from about 0.5 sccm to about 50 sccm, from about 1 sccm to about 30 sccm, for example, about 10 sccm. The halogen-based precursor can be provided along with a carrier gas, such as argon or nitrogen. The carrier gas may have a flow rate within the range from about 1 sccm to about 1000 sccm, such as from about 2 sccm to about 80 sccm, from about 5 sccm to about 40 sccm, for example, about 20 sccm.

In some embodiments, the metal oxide precursor is a metal organic precursor comprising an organic ligand. For example, the metal source can be a hafnium precursor which is a tetrakis (dialkylamino) hafnium compound, such as tetrakis (dimethylamino) hafnium (TDMAH), tetrakis (diethylamino) hafnium (TDEAH), or tetrakis (ethylmethylamino) hafnium (TEMAH).

The metal oxide precursor can be dispensed into a deposition chamber by introducing a carrier gas through an ampoule containing the organic precursor. An ampoule unit can include an ampoule, a bubbler, a canister, a cartridge, or other container used for storing, containing, or dispersing chemical precursors. For example, the ampoule can contain a liquid precursor (e.g., TDMAH or TDEAH) and be part of a liquid delivery system containing injector valve system used to vaporize the liquid precursor with a heated carrier gas. Generally, the ampoule can be heated to a temperature of about 180° C. or less, such as within a range from about 30° C. to about 180° C., for example, about 50° C. Alternatively, the precursor can be in gaseous form, and can be delivered directly to the deposition. The precursor can be in solid form, such as HfCl₄, and can be vaporized from solid to vapor, for example, upon heating to above 150C to achieve relatively high vapor pressure.

The oxidizing agent (e.g., O₂, O₃, H₂O) may be pulsed, introduced, or otherwise provided into the deposition chamber at a flow rate within a range from about 0.01 seconds to about 60 seconds, depending on the particular process conditions, oxygen source gas or oxidizing agent or desired composition of the deposited metal oxide material. In some embodiments, such as for forming a metal-poor oxide material, the oxidizing agent may be pulsed, introduced, or otherwise provided into the deposition chamber at a rate within a range from about 0.001 seconds to about 1 second, such as from about 0.001 seconds to about 0.1 seconds, for example, about 0.05 seconds. The oxidizer may be delivered to the process chamber by known methods. For example, a water vapor generator is used to generate water vapor and deliver (or pulse) it to the process chamber as the oxidizer. Ozone may be formed inside or outside of the deposition chamber, such as the ALD chamber. In some embodiments, the oxidizing agent contains ozone formed by an ozone generator positioned outside of the deposition chamber. Ozone is generated and then flowed or directed into the deposition chamber and exposed along with the metal source gas to the substrate surface. In some embodiments, the oxidizing agent contains ozone formed by a plasma generated within the interior of the deposition chamber. Oxygen gas flowed or directed into the deposition chamber, then ignited or formed into ozone and/or atomic oxygen before being sequentially exposed along with the precursor to the substrate surface.

The chamber may be purged between oxidizing and precursor exposure, and between repeating cycles of exposure to the oxidizer and precursor, and the cycles may be repeated a desired number of times. The purging process may use an inert gas or inactive gas, for example, such as nitrogen, argon, helium, mixtures thereof, or combinations thereof. The purge time may be any desired time for removing excess reactant from the chamber.

A carrier gas or a purge gas can be provided at the same time as the metal oxide precursor and/or the oxidant precursor, but can be also provided between the pulses of the metal oxide precursor and/or the oxidant precursor. The carrier gas or purge gas can flow continuously during the ALD process or can be intermediately and/or sequentially pulsed, introduced, or otherwise provided during the ALD process. The carrier gas or purge gas may be pulsed, introduced, or otherwise provided into the deposition chamber at a rate within a range from about 1 second to about 60 seconds, depending on the particular process conditions, source gases, or desired composition of the deposited metal oxide material. In some embodiments, the carrier gas or a purge gas may be pulsed, introduced, or otherwise provided into the deposition chamber at a rate within a range from about 1 second to about 30 seconds, such as from about 2 seconds to about 20 seconds, for example, about 10 seconds or about 15 seconds. Other purging times can be used.

The carrier gas or the purge gas may be sequentially pulsed, introduced, or otherwise provided after each pulse of the metal precursor and each pulse of the oxidizing agent during the ALD cycle. The pulses of purge gas or carrier gas are typically pulsed, introduced, or otherwise provided at a flow rate within a range from about 2 standard liters per minute (slm) to about 22 slm, such as about 10 slm. Other purging flows can be used.

Once the desired number of cycles of alternating exposure to the oxidizer and precursor are carried out, a post-deposition anneal may be performed to densify the film stack. The post-deposition anneal may be a high temperature bake, a post-oxidation anneal, or a high temperature anneal in the presence of a non-oxidizing gas, such as N₂. In some embodiments, the substrate temperature during the post-deposition anneal is in the range of about 500-1000° C., such as about 550-800° C. Exemplary post-deposition anneals include exposure to nitrous oxide at about 600° C. or exposure to nitrogen at about 800° C. The anneal may be performed for any desired amount of time. By way of example and not limitation, the anneal may be performed for about 30 seconds up to 30 minutes, or about 5-20 minutes, for example about 10 minutes. In some embodiments, a low temperature post-deposition anneal may be carried out, for example at a temperature below about 500° C., such as about 250-450° C. In some embodiments, a flow rate of up to about 20 slm, for example about 0.1-5 slm, may be used for the oxidation gas or non-oxidizing gas.

In some embodiments, a substrate is provided in a process chamber. The substrate can be a semiconductor substrate such as a silicon substrate. In some embodiments, the substrate is already processed to form appropriate structures for semiconductor devices. For example, n well and p well regions can be formed for forming a foundation for p-type and n-type transistors. In some embodiments, the substrate surface is conditioned for ALD deposition, for example, by providing an OH terminated surface. The OH surface can be prepared by exposing the substrate to water.

In some embodiments, a hafnium chloride (HfCl₄) precursor is introduced to the process chamber. The hafnium chloride precursor reacts with the OH surface to form hafnium oxygen bonding, thus binding the precursor to the surface. The unreacted hafnium chloride precursor is purged from the chamber. An oxidant, (e.g. water) is introduced to the process chamber. The water molecules react with the hafnium precursor bonded to the surface to form hafnium oxide. The process cycle continues, for example, by introducing hafnium chloride precursor followed by oxidant pulses to form a hafnium oxide layer.

The above description shows an example of ALD hafnium oxide deposition using HfCl₄ precursor and H₂O oxidant. The behaviors of other precursors and oxidants are similar, such as HfCl₄ with ozone. This cycle is repeated until a first high-k layer is formed with a thickness of about 0.3 nm.

In some embodiments, a second high-k layer then can be formed on the first high-k layer, for example, by reacting a metal organic-based hafnium precursor with an oxidant, which can be the same or different oxidant used in the formation of the first high-k layer. For example, for ALD reaction using a TDMAHf precursor and O₃ as an oxidant, the flow rate and concentration of ozone can be optimized to achieve hafnium oxide layer with good electrical performance. For example, low concentration and low flow of ozone can be used, followed by high concentration and high flow to obtain less ozone diffusion to the interface with high oxygen concentration in the bulk hafnium oxide layer.

In some embodiments, the present invention discloses a method to form a gate dielectric for a semiconductor device. The method includes providing a silicon-containing substrate; depositing a layer of hafnium oxide on the substrate using an ALD process comprising alternating a halogen-based hafnium precursor and an oxygen-containing precursor. The ALD process can deposit a layer having less than 10 monolayer thickness or less than 0.3 nm thickness.

In some embodiments, the present invention discloses a method to form a bi-layer gate dielectric for a semiconductor device. The method includes providing a silicon-containing substrate; depositing a first layer of hafnium oxide on the substrate using an ALD process comprising alternating a halogen-based hafnium precursor and an oxygen-containing precursor; and depositing a second layer of hafnium oxide on the first layer using an ALD process comprising alternating a metal organic-based hafnium precursor and an oxygen-containing precursor or a plasma oxygen precursor. The ALD process for depositing the first layer can have between 1 to 10 ALD cycles, or for less than 10 monolayer thickness, or for less than 0.3 nm thickness. The ALD process can have between 5 to 40 ALD cycles, or for depositing a second layer having less than 10 monolayer thickness or for less than 2 nm thickness.

In some embodiments, the present invention discloses an ALD process to form a gate dielectric, including depositing a first number of cycles with a halogen-based hafnium precursor and a first oxidant, followed by a second number of cycles with a metal organic-based hafnium precursor and a second oxidant, which can be the same or different from the first oxidant.

In some embodiments, methods to form a semiconductor device, including forming a bi-layer of hafnium oxide/hafnium oxide gate dielectric on a semiconductor substrate, followed by forming a transistor structure on the gate dielectric. The gate dielectric can be formed by a two step ALD deposition process, including a first step of using a halogen-based hafnium precursor and a second step of using a metal organic-based hafnium precursor.

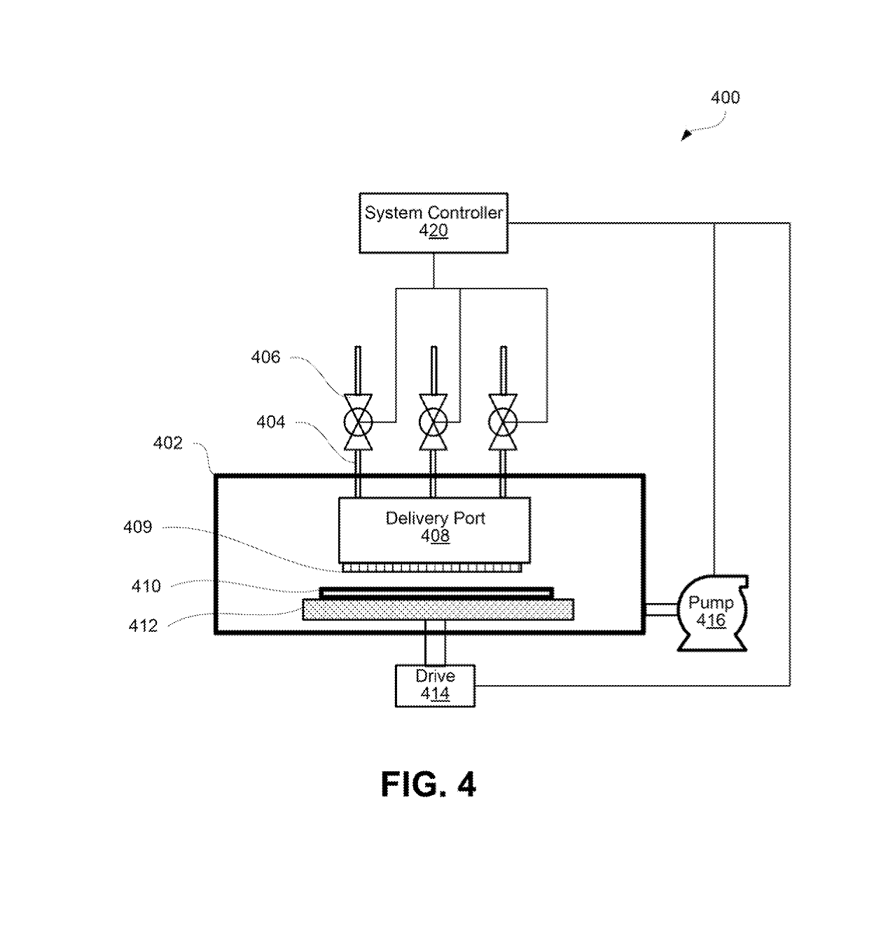

FIG. 4 illustrates a schematic representation of atomic layer deposition apparatus, 400, for fabricating MOS devices, in accordance with some embodiments. For clarity, some components of apparatus, 400, are not included in this figure, such as a wafer-loading port, wafer lift pins, and electrical feedthroughs. Apparatus, 400, includes deposition chamber, 402, connected to processing gas delivery lines, 404. While FIG. 4 illustrates three delivery lines, 404, any number of delivery lines may be used. Each delivery line, 404, may be equipped with a valve and/or mass flow controller, 406, for controlling the delivery rates of processing gases into deposition chamber, 402. In some embodiments, gases are provided into delivery port, 408, prior to exposing substrate, 410, to processing gases. Delivery port, 408, may be used for premixing gases (e.g., precursors and diluents) and even distribution of gases over the surface of substrate, 410. Delivery port, 408, is sometimes referred to as a showerhead. Delivery port, 408, may include a diffusion plate, 409, having multiple holes for gas distribution.

Deposition chamber, 402, encloses substrate support, 412, for holding substrate, 410, during its processing. Substrate support, 412, may be made from a thermally conducting metal (e.g., tungsten, molybdenum, aluminum, nickel) or other like materials (e.g., a conductive ceramic) and may be used to maintain the substrate temperature at desired levels. Substrate support, 412, may be connected to drive, 414, for moving substrate, 410, during loading, unloading, process set up, and sometimes even during processing. Deposition chamber, 402, may be connected to vacuum pump, 416, for evacuating reaction products and unreacted gases from deposition chamber, 402, and for maintaining the desirable pressure inside chamber, 402.

Apparatus, 400, may include system controller, 420, for controlling process conditions during electrode and resistive switching layer deposition and other processes. Controller, 420, may include one or more memory devices and one or more processors with a central processing unit (CPU) or computer, analog and/or digital input/output connections, stepper motor controller boards, and the like. In some embodiments, controller, 420, executes system control software including sets of instructions for controlling timing, gas flows, chamber pressure, chamber temperature, substrate temperature, radio frequency (RF) power levels (if RF components are used, e.g., for process gas dissociation), and other parameters. Other computer programs and instruction stored on memory devices associated with controller may be employed in some embodiments.

Although the foregoing examples have been described in some detail for purposes of clarity of understanding, the invention is not limited to the details provided. There are many alternative ways of implementing the invention. The disclosed examples are illustrative and not restrictive.

1. A method comprising:
providing a substrate, wherein the substrate comprises germanium;
depositing a first high-k layer comprising a first high-k material above the substrate using a first atomic layer deposition (ALD) process using a halogen-based precursor;
wherein the first high-k material is a first stoichiometric oxide;
wherein the first high-k layer has a first thickness of about 0.3 nm;
depositing a second high-k layer comprising a second high-k material on the first high-k layer using a second ALD process;
wherein the second ALD process comprises using a second precursor;
wherein the second precursor comprises a metal organic-based precursor,
wherein the second high-k material is a second stoichiometric oxide; and
wherein the second high-k layer has a second thickness of between 0.3 nm and 3 nm.

2. The method of claim 1, wherein the first stoichiometric oxide comprises at least one of hafnium, zirconium, or titanium.

3. The method of claim 2, wherein the first stoichiometric oxide comprises titanium.

4. The method of claim 3, wherein the halogen-based precursor comprises at least one of fluorine, chlorine, or iodine.

5. The method of claim 4, wherein the halogen-based precursor comprises iodine.

6. The method of claim 1, wherein the halogen-based precursor comprises titanium iii iodide.

7. The method of claim 1, wherein the first ALD process uses an oxidant to form the first high-k material,
wherein the oxidant comprises at least one of oxygen, ozone, or water.

8. (canceled)

9. The method of claim 1, wherein the metal organic-based precursor comprises at least one of β-diketonate precursors, alkoxide precursors, or amino precursors.

10. The method of claim 9, wherein the metal organic-based precursor comprises an amino precursor.

11. The method of claim 10, wherein the metal organic-based precursor comprises at least one of tetrakis(dimethylamino)hafnium (TDMAH), tetrakis(diethylamino)hafnium (TDEAH), or tetrakis(ethylmethylamino)hafnium (TEMAH).

12. The method of claim 11, wherein the metal organic-based precursor comprises tetrakis(dimethylamino)hafnium (TDMAH).

13. The method of claim 1, wherein an oxidant used to form the second high-k material comprises at least one of oxygen, ozone, or water.

14. The method of claim 1, wherein the second high-k layer has a second thickness of between about 0.3 nm and 1.5 nm.

15. The method of claim 1, wherein at least one of the depositing the first high-k layer or the depositing the second high-k layer is performed at a pressure between about 0.5 Torr and 2 Torr.

16. The method of claim 1, wherein at least one of the depositing the first high-k layer or the depositing the second high-k layer is performed for a time between about 0.25 minutes and 60 minutes.

17. The method of claim 1, wherein at least one of the depositing the first high-k layer or the depositing the second high-k layer is performed at a temperature between about 100° C. and 500° C.

18. The method of claim 1, further comprising
performing a post-deposition anneal process on the substrate after the depositing the second high-k layer.

19. The method of claim 18, wherein the post-deposition anneal process is performed at a temperature between about 500° C. and 1000° C.

20. The method of claim 18, wherein the post-deposition anneal process is performed at a time between about 30 seconds and 30 minutes.

21. The method of claim 19, wherein the post-deposition anneal process is performed at a temperature between about 550° C. and 800° C.
